(19) United States
(12) Patent Application Publication
(10) Pub. No.: US 2025/0113626 A1
(43) Pub. Date: Apr. 3, 2025

(54) WIRE-IN-DAM PACKAGES AND RELATED SYSTEMS AND METHODS

(71) Applicant: SEMICONDUCTOR COMPONENTS INDUSTRIES, LLC, Scottsdale, AZ (US)

(72) Inventors: Michael J. SEDDON, Gilbert, AZ (US); Gregg BARDEL, San Jose, CA (US)

(73) Assignee: SEMICONDUCTOR COMPONENTS INDUSTRIES, LLC, Scottsdale, AZ (US)

(21) Appl. No.: 18/478,296

(22) Filed: Sep. 29, 2023

(51) Int. Cl. H01L 27/146

(52) U.S. Cl. CPC H10F 39/011; H10F 39/804; H10F 39/811

(57) ABSTRACT

An electromagnetic irradiation system may include a bulb assembly and a light emitting diode panel. The bulb assembly and light emitting diode panel may be coupled over a package tray conveyor and the bulb assembly and the light emitting diode panel may be configured so that a package tray including a plurality of image sensor packages encounters irradiation from the light emitting diode panel prior to encountering irradiation from the bulb assembly.

### BACKGROUND

### 1. Technical Field

Aspects of this document relate generally to semiconductor packages, such as packages for image sensor devices.

### 2. Background

Various semiconductor packages have been devised that work to provide electrical connections for semiconductor die with a motherboard or circuit board to which a semiconductor package is attached. Various semiconductor package designs also work to provide protection for a semiconductor device from humidity, shock, vibration, or electrostatic discharge.

### SUMMARY

An electromagnetic irradiation system may include a bulb assembly and a light emitting diode panel. The bulb assembly and light emitting diode panel may be coupled over a package tray conveyor and the bulb assembly and the light emitting diode panel may be configured so that a package tray including a plurality of image sensor packages encounters irradiation from the light emitting diode panel prior to encountering irradiation from the bulb assembly.

Implementations of an electromagnetic irradiation system may include one, all, or any of the following:

The light emitting diode panel may be a first light emitting diode panel and a second light emitting diode panel may be coupled over the package tray conveyor.

The first light emitting diode panel and second light emitting diode panel may be oriented opposing one another with a face of the first light emitting diode panel and a face of the second light emitting diode panel each oriented at an angle relative to a plane formed by the package tray conveyor.

The angle may be between 30 degrees and 45 degrees.

The angle may be 45 degrees.

The irradiation from the bulb assembly and from the light emitting diode panel may be ultraviolet radiation.

The ultraviolet radiation may be used in curing an optically transmissive cover adhesive material.

Implementations of a method of applying a protective layer may include providing an image sensor die including a plurality of bond pads; bonding a plurality of bond wires coupled to the plurality of bond pads; applying a protective layer over the plurality of bond wires and the plurality of bond pads; curing the protective layer; applying an adhesive material directly over the protective layer; attaching an optically transmissive cover to the adhesive material; and curing the adhesive material.

Implementations of a method of applying a protective layer may include one, all, or any of the following:

The optically transmissive cover may include a black mask material applied around a perimeter of the optically transmissive cover.

Curing the adhesive material may include one of using ultraviolet light, thermal energy, or any combination thereof.

The protective layer may include one of a mold compound, an acrylic compound, an organic compound, an epoxy compound, or any combination thereof.

The protective layer may include a material that may be the same as the adhesive material.

Curing the protective layer may include one of using ultraviolet light, thermal energy, or any combination thereof.

The method may include bonding the image sensor die to a substrate.

Implementations of a cover for an image sensor package may include an optically transmissive cover including a largest planar side including a perimeter having four corners; and a black mask layer applied onto the largest planar side adjacent to the perimeter forming a mask pattern. The mask pattern of the black mask layer may expose all four corners of the perimeter.

Implementations of a cover for an image sensor package may include one, all, or any of the following:

The mask pattern may include four segments and only two of the four segments may be connected.

The mask pattern may include a stipple pattern.

The mask pattern may include a half tone pattern.

The mask pattern may be configured to overlap a perimeter of an image sensor die when the optically transmissive cover may be coupled over the image sensor die.

The largest planar side may be one of a largest planar side configured to face the image sensor die or a largest planar side of the optically transmissive cover opposing the largest planar side configured to face the image sensor die.

Implementations of a method of applying an adhesive material may include providing an image sensor die including a plurality of bond pads; bonding a plurality of bond wires coupled to the plurality of bond pads. The method may also include, to maintain a substantially consistent width and height of adhesive material, doing one of: increasing and decreasing a speed of a dispensing nozzle dispensing the adhesive material over the bond pads and bond wires; increasing and decreasing a volume of adhesive material dispensed over the bond pads and bond wires; or increasing and decreasing a pressure on the adhesive material during dispensing.

Implementations of a method of applying an adhesive material may include providing an image sensor die including a plurality of bond pads; bonding a plurality of bond wires coupled to the plurality of bond pads; driving a dispensing nozzle in an application path that applies an adhesive material at an edge of an image sensor die over the plurality of bond wires and plurality of bond pads to form a consistently straight sidewall edge of the adhesive material; coupling an optically transmissive cover over the adhesive material after applying the adhesive; and using electromagnetic irradiation to at least partially cure the adhesive material.

Implementations of a method of applying an adhesive material may include one, all, or any of the following:

Coupling the optically transmissive cover over the adhesive material further may include forming a sidewall profile of the adhesive material that may be substantially parallel with a sidewall of the image sensor die.

Implementations of a method of curing adhesive material for an optically transmissive cover may include providing a plurality of image sensor packages including an optically transmissive cover coupled to an image sensor die using an adhesive material; and coupling each of the plurality of image sensor packages into a corresponding opening of a plurality of openings in a package tray. The method may also include curing the adhesive material by doing one of: placing the package tray under an electromagnetic irradiation source and rotating the package tray in a plane formed by the largest planar surface of the package tray; placing the package tray under electromagnetic irradiation, lifting the package tray and one of: rotating the package tray in a plane formed by the largest planar surface of the package tray; tilting the package tray along a shortest axis of the package tray; tilting the package tray along a longest axis of the package tray; or any combination thereof.

Implementations of a method of curing adhesive material for an optically transmissive cover may include one, all, or any of the following:

The method may include rotating the electromagnetic irradiation source, rotating a set of reflectors and the electromagnetic irradiation source, or any combination thereof.

Implementations of a method of curing adhesive material for an optically transmissive cover may include providing a plurality of image sensor packages including an image sensor die coupled to an optically transmissive cover using an adhesive material; and coupling each of the plurality of image sensor packages into a corresponding opening of a plurality of openings in a package tray. The method may also include curing the adhesive material by doing one of: enclosing one of the plurality of image sensor packages in a spherical enclosure or ellipsoidal enclosure and irradiating the image sensor package using an electromagnetic irradiation source optically coupled with the spherical enclosure or ellipsoidal enclosure; enclosing the plurality of image sensor packages in a corresponding plurality of spherical enclosures or plurality of ellipsoidal enclosures and irradiating the image sensor package using at least one electromagnetic irradiation source optically coupled with the plurality of spherical enclosures or plurality of ellipsoidal enclosures; enclosing the package tray and plurality of image sensor packages in a solid including one of a corresponding plurality of spherical openings or plurality of ellipsoidal openings and irradiating the image sensor package using at least one electromagnetic irradiation source optically coupled with the plurality of spherical openings or plurality of ellipsoidal openings; exposing sidewalls of the plurality of image sensor packages in the package tray using irradiation from a corresponding plurality of fiber optic cables; exposing sidewalls of the plurality of image sensor packages in the package tray using irradiation from a fiber optic cable by moving the fiber optic cable from image sensor package to image sensor package in the package tray; or any combination thereof.

Implementations of a method of curing adhesive material for an optically transmissive cover may include one, all, or any of the following:

Enclosing the plurality of image sensor packages in a spherical enclosure or ellipsoidal enclosure further may include changing one of a vertical position, horizontal position, or rotational position relative to the image sensor package during irradiation.

Moving the fiber optic cable from image sensor package to image sensor package further may include one of moving using a robotic arm, moving using a conveyor, or any combination thereof.

Implementations of a cover for an image sensor package may include an optically transmissive cover including a largest planar side including a perimeter having four corners; and a black mask layer applied onto the largest planar side adjacent to the perimeter forming a mask pattern. The perimeter of the optically transmissive cover may be configured to overhang a perimeter of an image sensor die by 50 microns or less.

Implementations of a cover for an image sensor package may include one, all, or any of the following:

The perimeter of the optically transmissive cover may be configured to overhang the perimeter of the image sensor die by 0 microns or less.

The perimeter of the optically transmissive cover may be configured overhang the perimeter of the image sensor die by −5 microns or less.

The perimeter of the optically transmissive cover may include four sides and wherein at least one side of the four sides may be configured to overhang a corresponding side of the perimeter of the image sensor die by less than an overhang of at least one other side of the four sides of the optically transmissive cover.

Implementations of an electrical interconnect for an image sensor package may include a bond wire wirebonded to one of: a pad including aluminum; or an over pad layer directly coupled to a pad including aluminum, the over pad layer including one of nickel/gold, nickel/palladium/gold, nickel/palladium, copper, copper/nickel/gold, and any combination thereof where the bond wire may include one of gold, copper, palladium coated copper, silver, or any combination thereof.

Implementations of a method of applying a black mask may include providing an image sensor die including a plurality of bond pads; bonding a plurality of bond wires coupled to the plurality of bond pads; applying an adhesive material over the plurality of bond wires and the plurality of bond pads; attaching an optically transmissive cover to the adhesive material; and at least partially curing the adhesive material using electromagnetic irradiation. The method may also include after at least partially curing the protective layer, applying a black mask material around a perimeter of the optically transmissive cover.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of an image sensor package;

FIG. 2 is a top view of an implementation of an image sensor package showing a black mask material;

FIG. 3 is a diagram of the electrical field surrounding bond connection in a wire-in-dam image sensor package;

FIG. 4 is a cross sectional view of an first implementation of a wire bond of a wire-in-dam image sensor package;

FIG. 5 is a cross sectional view of a second implementation of a wire bond of a wire-in-dam image sensor package;

FIG. 6 is a cross sectional view of a third implementation of a wire bond of a wire-in-dam image sensor package;

FIG. 7 is a cross sectional view of a fourth implementation of a wire bond of a wire-in-dam image sensor package;

FIG. 8 is a diagram showing the placement of black mask material and adhesive material relative to an image sensor die in two alternative arrangements;

FIG. 9 is a ray tracing diagram of rays of ultraviolet (UV) light in an implementation of an electromagnetic irradiation system;

FIG. 10 is a diagram showing movement of a package tray with a plurality of image sensor packages thereon through an implementation of an electromagnetic irradiation system;

FIG. 11 is a diagram showing movement of a package tray with a plurality of image sensor packages thereon through a second implementation of an electromagnetic irradiation system;

FIG. 12 illustrates the shadowing effect of UV light emitted by an implementation of a light emitting diode (LED) panel of an electromagnetic irradiation system oriented at 45 degrees to a package tray with a plurality of image sensor packages thereon;

FIG. 13 illustrates the shadowing effect of UV emitted by a light emitting diode panel of an electromagnetic irradiation system oriented at 30 degrees to a package tray with a plurality of image sensor packages thereon;

FIG. 14 is a partial view of the structure of an implementation of an electromagnetic irradiation system showing a heat map of the UV light intensity across a package tray;

FIG. 15 is a perspective view of an implementation of a package tray rotating under UV irradiation on a surface of a conveyor/transport of an electromagnetic irradiation system;

FIG. 16 is a perspective view of an implementation of a package tray rotating while raised above a surface of a conveyor/transport of an electromagnetic irradiation system;

FIG. 17 is a perspective view of an implementation of a package tray rotating in various axes while raised above a surface of a conveyor/transport of an electromagnetic irradiation system;

FIG. 18 is a partial view of the structure of an implementation of an electromagnetic irradiation system showing rotation of the primary reflectors and secondary reflectors above a package tray;

FIG. 19 is a partial view of the structure of an implementation of an electromagnetic irradiation system showing rotation of an LED panel and rotation of reflectors above package trays during processing;

FIG. 20 is a see through view of a fiber optic cable coupled with a spherical enclosure resting over an image sensor package in a package tray during a UV curing operation;

FIG. 21 a see through view of a plurality of fiber optic cable coupled with a plurality of spherical enclosures each resting over an individual image sensor package in a package tray during a UV curing operation;

FIG. 22 is a see through view of a plurality of spherical voids each coupled with a fiber optical cable in a solid placed over a plurality of image sensor packages in a package tray during a UV curing operation;

FIG. 23 is a see through view of a fiber optic cable coupled with an ellipsoidal enclosure resting over an image sensor package in a package tray during a UV curing operation;

FIG. 24 is a see through view of a fiber optic cable coupled with a spherical enclosure being rotated over an image sensor package in a package tray during a UV curing operation;

FIG. 25 is a see through view of two fiber optic cables coupled with a spherical enclosure resting over an image sensor package in a package tray during a UV curing operation;

FIG. 26 is a perspective view of a set of fiber optic cables directing UV light toward image sensor packages in a package tray during a UV curing operation;

FIG. 27 is a perspective view of a fiber optic cable being manipulated by a control arm to direct UV light toward an image sensor package in a package tray during a UV curing operation;

FIG. 28 is a cross sectional view of a first implementation of a wire-in-dam image sensor package;

FIG. 29 is a cross sectional view of a second implementation of a wire-in-dam image sensor package;

FIG. 30 is a cross sectional view of a third implementation of a wire-in-dam image sensor package;

FIG. 31 is a cross sectional view of a fourth implementation of a wire-in-dam image sensor package;

FIG. 32 is a top view of an implementation of a substrate with bond pads with an image sensor coupled thereto;

FIG. 33 is a top view of an implementation of a substrate with bond pads with a protective layer applied over some of the bond pads;

FIG. 34 is a top view of the implementation of FIG. 33 with an adhesive material applied over all the bond pads including the protective layer;

FIG. 35 is a top view of an implementation of a substrate with bond pads with an image sensor coupled thereto;

FIG. 36 is a top view of an implementation of a substrate with a protective layer applied over all of its bond pads;

FIG. 37 is a top view of the implementation of the substrate of FIG. 36 with an adhesive material applied over the protective layer;

FIG. 38 is a cross sectional view of an implementation of a substrate with pads thereon and an image sensor die;

FIG. 39 is a cross sectional view of the substrate of FIG. 38 following application of a protective/plating layer thereon;

FIG. 40 is a cross sectional view of the substrate of FIG. 39 following formation of an overpad layer directly to the pads;

FIG. 41 is a cross sectional view of the substrate of FIG. 40 following removal of the protective/plating layer thereon;

FIG. 42 is a cross sectional view of an implementation of a wire-in-dam image sensor package during a UV curing process;

FIG. 43 is a cross sectional view of the package implementation of FIG. 42 following application of a black mask material to the optically transmissive cover;

FIG. 44 is a cross sectional view of the package implementation of FIG. 42 following application of a black mask material to sidewalls of the optically transmissive cover and to a largest planar surface of the optically transmissive cover;

FIG. 45 is a top view of an implementation of an implementation of a wire-in-dam image sensor package with an optically transmissive cover having a black mask material applied around its perimeter except at corners of the optically transmissive cover;

FIG. 46 is a perspective view of the image sensor package of FIG. 45;

FIG. 47 is a diagram of a stipple pattern that can be used with black mask material to form a black mask layer on an implementation of an optically transmissive cover;

FIG. 48 is a detail view of an adhesive material applied over a plurality of bond pads showing the side wall shape of the adhesive material; and

FIG. 49 is a detail view of an adhesive material applied over a plurality of bond pads showing the side wall shape of the adhesive material.

### DESCRIPTION

This disclosure, its aspects and implementations, are not limited to the specific components, assembly procedures or method elements disclosed herein. Many additional components, assembly procedures and/or method elements known in the art consistent with the intended wire-in-dam packages and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such wire-in-dam packages, and implementing components and methods, consistent with the intended operation and methods.

Referring to FIG. 1, an implementation of a wire-in-dam image sensor package 2 is illustrated. The term “wire-in-dam” refers to the presence of the bond wires 4 (and the wire bonds and bond pads) inside the adhesive material 6 that holds the optically transmissive cover 8 to the image sensor die 10. The adhesive material 6 is distributed around the perimeter of the image sensor die 10 and so acts like a dam preventing air flow and other contaminants from entering the air gap 12 between the optically transmissive cover 8 and the pixel array 14 of the image sensor die 10. In various implementations, the adhesive material is a glass attach epoxy material. Mold compound 16 is used to cover the remainder of the bond wires 4 and edge of the substrate 18 to which the image sensor die 10 is attached. In this case, the substrate 18 includes a ball grid array 20 which routes electrical signals from the image sensor die 10 to a motherboard or circuit board to which the wire-in-dam image sensor package 2 is attached.

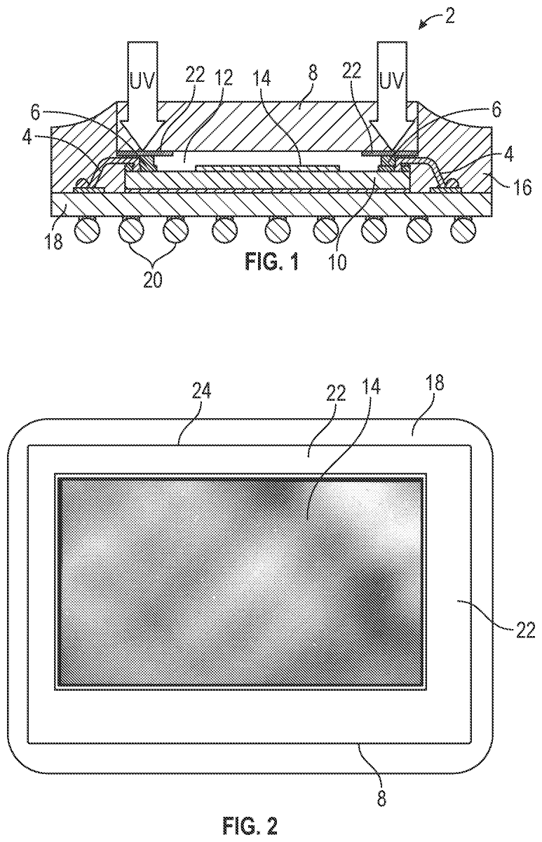

One of the optical challenges presented by wire-in-dam image sensor packages is that the material of the bond wires 4 and associated pads to which the bond wires 4 are attached can reflect incoming electromagnetic radiation (visible light, ultraviolet light, infrared light, x-rays, gamma rays, or any other type of electromagnetic radiation) as scattered light toward the pixel array 14. This can create negative effects on the resulting images produced by the image sensor die 10 including artifacts like flare. To help mitigate the reflection, black mask material (black mask layer) 22 is placed between the adhesive material 6 and the optically transmissive cover to absorb electromagnetic radiation heading toward the bond wires 4 and prevent it from reaching them. FIG. 2 illustrates a top down view of a wire-in-dam image sensor package showing the outline of the black mask material 22 around the pixel array 14 and the position of the substrate 18. Note that the width of the black mask material 22 around the perimeter of the image sensor die may vary depending on which side of the optically transmissive cover 8 the black mask material 22 is located. In the wire-in-dam package implementations illustrated in FIGS. 1 and 2, the black mask material 22 is applied around the perimeter 24 of the optically transmissive cover 8 prior to the optically transmissive cover being applied to the adhesive material 6 by dropping or placing onto the adhesive material 6.

In various wire-in-dam image sensor package implementations, the material of the adhesive material 6 requires curing to firmly hold the optically transmissive cover 8 to the image sensor die 10. In various implementations, the adhesive material 6 is cured using both ultraviolet (UV) light/ultraviolet radiation and thermal energy. In particular implementations, the UV light is used to cure the adhesive material 6 to a certain tackiness/stiffness prior to the application of thermal energy because the use of thermal energy only to cure has been observed to result in some implementations to cause blowouts or voids in the optically transmissive cover 8 away from the image sensor die 10. Thus the use of the UV light curing process in conjunction with thermal energy curing assists with establishing a reliable air-tight seal between the optically transmissive cover 8 and the image sensor die 10 that will not later experience a failure due to voids or cracks in the gap between the optically transmissive cover 8 and the material of the adhesive material 6. In various package implementations, the use of UV curing allows the optically transmissive cover 8 to maintain its position in X and Y and vertically above the image sensor die (height) during a subsequent thermal curing operation. In these implementations, the UV cure prevents the adhesive material from becoming more fluid during the elevated temperature of the thermal curing operation and allowing the position of the optically transmissive cover to shift.

A consequence of the use of the black mask material 22 around the perimeter 24 of the optically transmissive cover 8 is that, as illustrated in FIG. 1, the black mask material 22 also blocks the UV light during the UV cure process just as it blocks other electromagnetic radiation during operation of the finished package. This means that the black mask material 22 casts a shadow over the adhesive material 6 for all rays of UV radiation that are incident on the dimensions of the black mask material 22. Thus the only UV radiation that can participate in curing the adhesive material 6 is that which comes in on/from the sides of the adhesive material 6, either through the optically transmissive cover 8 on the pixel array side or on the bond wire side of the dam formed by the adhesive material 6.

Reliance on the UV radiation available on the sides of the adhesive material 6 to carry out the UV curing process has led to mixed results. For example, position dependent effects have been observed in reliability failures that vary depending on where a particular bond pad is located along the perimeter of the image sensor die. The source of the reliability failures has also not been observed to be merely mechanical separation of the optically transmissive cover from the adhesive material (or the adhesive material from the image sensor die) but has also been observed to be the effect of corrosion of the wire bonds between the bond wires and the material of the bond pads themselves.

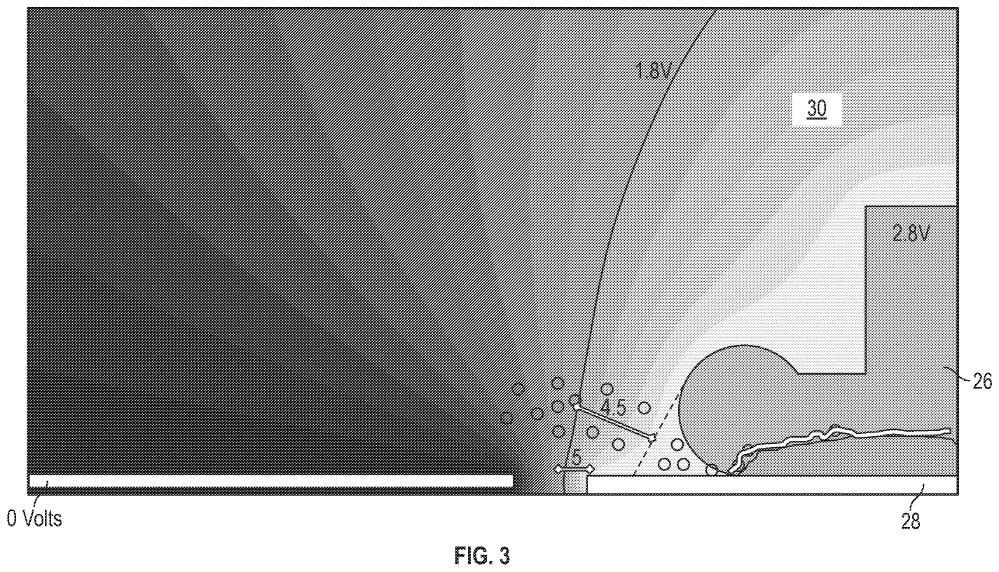

Referring to FIG. 3, an electrical potential diagram of the adhesive material 30 surrounding the wire bond 26 and bond pad 28 for a bond pad operating at 2.4 V is illustrated. A1s illustrated, the geometry of the wire bond connection with the pad aids in drawing mobile ions (chlorine, etc.) present in the adhesive material 30 toward the joint between the bond pad 28 and the wire bond 26. The result is that a corrosion process involving the mobile ions and the materials of the bond wire and of the bond pad begins to take place over a period of time. Eventually, for bond pad locations where sufficient ion mobility exists, the corrosion process continues until the entire wire bond 26 is corroded, leading to an electrical connection failure with the bond pad 28. Because the corrosion takes place over time, this type of failure presents a device reliability risk. Reliability testing has shown position dependency for these failures along with voltage dependency effects (higher voltage bond pads show more failures than lower voltage bond pads). Since the material of the adhesive material 30 is the same at the bond pads where failures are observed due to corrosion and where no failures are observed, the corrosion effect appears to be enhanced where the material of the adhesive material at the failing bond pads is less cured at the UV radiation process than the material at the non-failing bond pads.

Various solutions to the issue of how to increase the amount of curing taking place during the UV irradiation/radiation process for wire-in-dam image sensor packages are disclosed in this document.

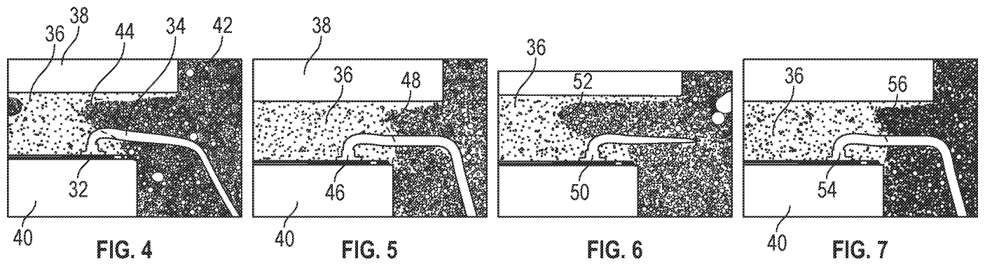

Referring to FIG. 4, a cross sectional view showing a wire bond 32 and bond wire 34 in the adhesive material 36 between optically transmissive cover 38 and image sensor die 40 and passing through mold compound 42 is illustrated. Here it can be observed that the edge profile 44 of the adhesive material is shifted inward from the edge of the image sensor die 40 and correspondingly, the cure achievable using UV radiation was reduced because of the black mask material attached to the optically transmissive cover 38. This particular wire bond 32 was observed to fail reliability testing due to corrosion caused by mobile chlorine and/or other halogen ions present in the adhesive material 36. Referring to FIG. 5, another wire bond 46 on the same image sensor die 40 is illustrated showing that the edge profile 48 of the adhesive material 36 was close to or substantially the same as/at the edge of the image sensor die 40. No reliability failure was observed for this wire bond 46 because the adhesive material located close to the edge of the image sensor die 40 received more UV radiation and thus cured more fully during the UV cure process than the adhesive material in FIG. 4.

FIG. 6 illustrates another wire bond 50 where the edge profile 52 of the adhesive material 36 is shifted inwardly again. This wire bond 50 experienced corrosion-related failure during reliability testing due to the lower UV curing that took place because of the higher degree of UV shadowing experienced by the adhesive material 36. Again, in contrast, the wire bond 54 illustrated in FIG. 7 did not experience failure during reliability testing because the sidewall profile 56 of the adhesive material 36 was shifted outward and was close to/substantially at the edge of the image sensor die 40.

Various methods of applying an adhesive material may be used to keep the sidewall profile at or substantially at the edge of the image sensor die. The methods include providing an image sensor die that includes a plurality of bond pads and bonding a plurality of bond wires to the plurality of bond pads. To maintain a substantially consistent width and height of material, in particular method implementations, a speed of a dispensing nozzle dispensing the adhesive material is increased and/or decreased. In another particular method implementation, a volume of adhesive material being dispensed by the dispensing nozzle over the plurality of bond pads and plurality of bond wires is increased and/or decreased. In another particular method implementation, a pressure applied to the adhesive material during dispensing through the dispensing nozzle may be increased and/or decreased. In yet another method implementation, any combination of increasing and/or decreasing speed, volume, and pressure may be used to maintain a substantially consistent width and height of adhesive material around the perimeter of the image sensor die. In this way the resulting edge profile after cover drop or placement may be consistent around the perimeter allowing for the UV curing achieved of the adhesive material to be correspondingly consistent around each bond pad and bond wire.

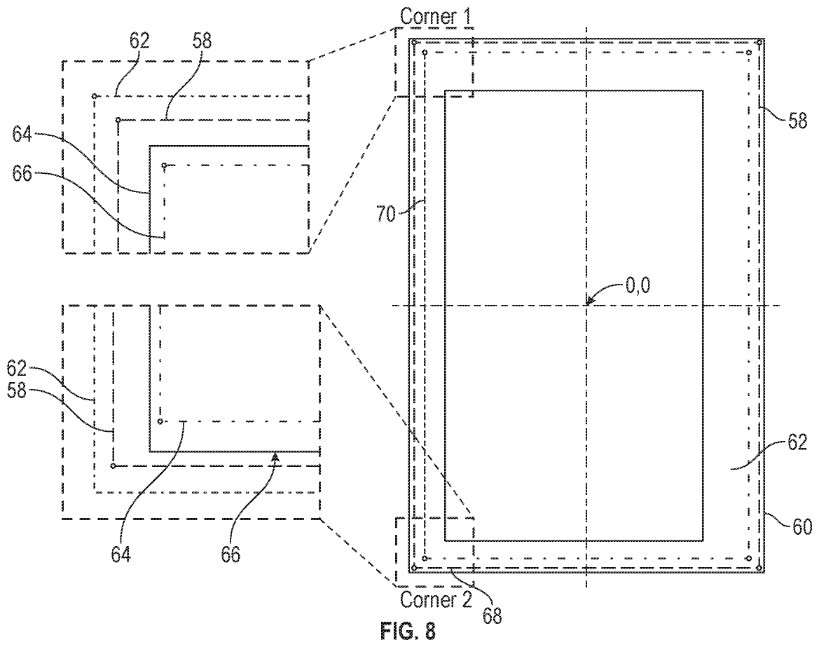

Referring to FIG. 8, an implementation of an image sensor die 58 is illustrated in partial see through with an implementation of an optically transmissive cover 60 above it with a black mask layer 62 coupled thereto. Detail corner views Corner 1 and Corner 2 in FIG. 8 show the overlap of the edges of the black mask layer 62 over the edges of the image sensor die 58. Detail corner views Corner 1 and Corner 2 also show a first path 64 and second path 66 indicating the position where adhesive material is dispensed on the surface of the image sensor die 58. In Corner 1, by inspection the second path 66 is offset downwardly from the first path 64 and in Corner 2, the second path 66 places the adhesive material further toward the edge of the image sensor die 58 than the first path 64 did. During reliability testing, it was noted that the wire bond 68 exhibited 0% corrosion while the wire bond 70 exhibited 100% corrosion on units made by dispensing adhesive material along the second path 66. The adhesive material at wire bond 68 had an edge profile closer to the edge of the image sensor die 58 than the edge profile at wire bond 70. This test indicates that, along with increases and decreases in speed, volume, or pressure of adhesive material being dispensed by the dispensing nozzle, placement of the bead of adhesive material being dispensed along the image sensor die also affects the resulting UV cure of the adhesive material by setting the location of the edge profile of the adhesive material. Accordingly, various method implementations may include setting a centerline of a bead of adhesive material being dispensed at a predetermined distance from the edge of the image sensor die. In some method implementations, the predetermined distance may be different for each side of the image sensor die. This may be done to accommodate a different pattern of the black mask layer 62 or to accommodate a different placement of the optically transmissive cover over the image sensor die where the center of the optically transmissive cover is not centered on the center of the image sensor die 58.

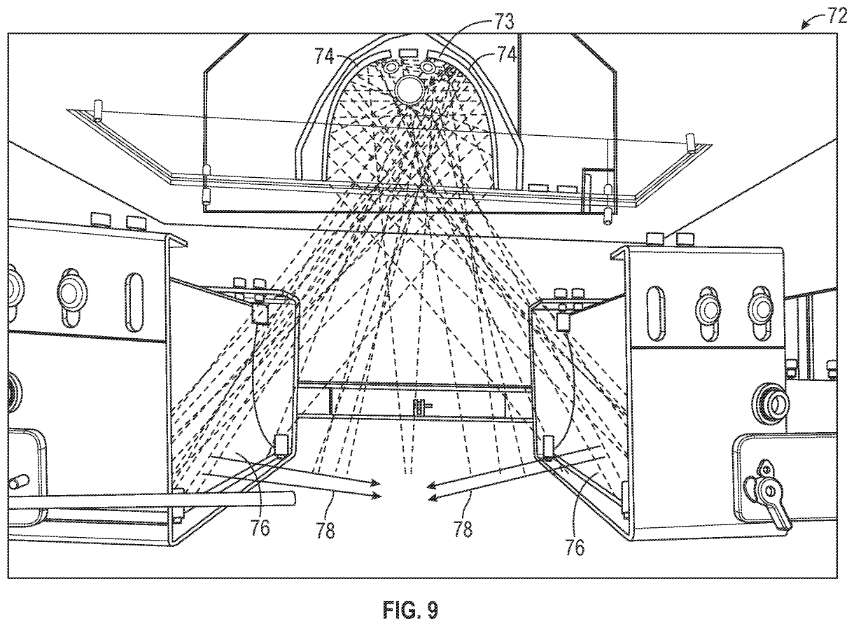

Referring to FIG. 9, a ray tracing diagram of rays of UV light in an implementation of an electromagnetic irradiation system 72 is illustrated. In this system, a package tray holding a plurality of wire-in-dam image sensor packages is designed to pass through in a direction into and out of the paper on a conveyor. In various implementations, the package tray may be designed to hold a set of packages at a specific stage in the packaging process; in other implementations, however, the package tray may be a strip which can contain multiple iterations of a package design in the form of an array of parts. As illustrated, the electromagnetic irradiation system 72 includes a bulb assembly 73 that includes bulb 74 (shown in a cross sectional view) surrounded by primary reflectors 74. Below the bulb assembly 73 is a set of secondary reflectors 76. FIG. 9 illustrates how the electromagnetic radiation emitted by the bulb 74 is diffusely emitted, meaning that it is emitted in all directions from the bulb (in contrast with coherently emitted, where all the electromagnetic radiation is directed in the same direction). The dotted lines in FIG. 9 indicate the path of various traced rays of diffusely emitted electromagnetic radiation from the bulb 73 as they travel downwardly toward the package tray which would be located in between the secondary reflectors 76.

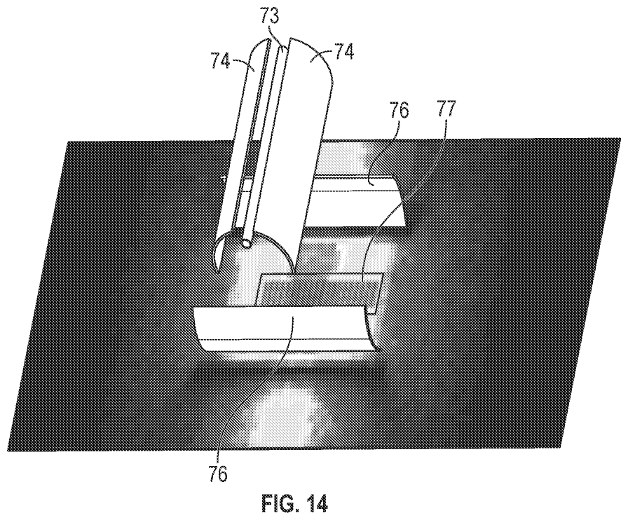

As illustrated in FIG. 9, most of the rays, except for rays 78 from the secondary reflectors 76, are directed downwardly at the top surfaces of the image sensor packages in the package tray. Referring to FIG. 14, this heatmap of the location of the electromagnetic radiation shows that the primary reflectors 74 and secondary reflectors 76 focus most of the electromagnetic radiation directly down on package tray 77 as it passes underneath. Because of this, most of the electromagnetic radiation will be blocked by the black mask of each image sensor package and not be able to participate in the curing operation. Where the electromagnetic radiation is UV light, as in the implementation of FIG. 9, this means that only the percentage of light rays that form rays 78 are actually available to participate in the UV curing process of the adhesive materials in each package tray. Furthermore, because the image sensor packages are arranged in rows and columns in the package tray, the sides of the image sensor packages that face the interior of the package tray experience a shadowing effect where UV light can be prevented from reaching the interior-facing sides due to the low angle of incidence between the rays 78 and the image sensor packages. Thus, because of the position of the black mask, though the electromagnetic irradiation system 72 generates considerable UV light, most of that light does not reach the material of the adhesive material because of the angle of the rays emitted diffusely from the bulb 73. Furthermore, because of the parallel arrangement of the secondary reflectors 76, the primary direction of the rays 78 is along only one axis of the image sensor packages, leaving the sides of the image sensor packages parallel with the direction of the rays 78 subject to less light exposure than the sides that are oriented perpendicularly to the direction of the rays 78.

Referring to FIG. 10, the orientation of the components of electromagnetic irradiation system 72 relative to package trays including a plurality of image sensor packages 80 is illustrated in this perspective view as the package trays travel through the system 72 on a conveyor in the direction of arrow 82. FIG. 11 illustrates another implementation of an electromagnetic irradiation system 84 shown in partial see through view with various covers of the system removed so that the bulb 86 and primary reflectors 88 along with the secondary reflectors 90 can be seen. Conveyor 92 is illustrated carrying package trays 94 in the direction of arrow 96.

As illustrated in FIG. 11, two light emitting diode (LED) panels 98 are supported over the conveyor and positioned over the package trays 94 before they enter the housing 100 of the electromagnetic irradiation system 84. The light emitting diode panels 98 emit electromagnetic radiation in the same or substantially the same wavelength(s) as the bulb 86, in this case UV radiation. In some implementations, the UV radiation may have a wavelength of about 365 nm. The specific UV radiation wavelength is chosen depending on the wavelength used/employed with the photoinitiator in the adhesive material being used. A position of each of the LED panels 98 is angled relative to the orientation of the package trays 94 on the conveyor 92. A face 102 of the LED panels 98 is also illustrated as being angled at an angle to a plane formed by the conveyor 92 (package tray conveyor). In various implementations, this angle may vary between about 30 degrees to about 45 degrees. In particular implementations, this angle may be about 45 degrees.

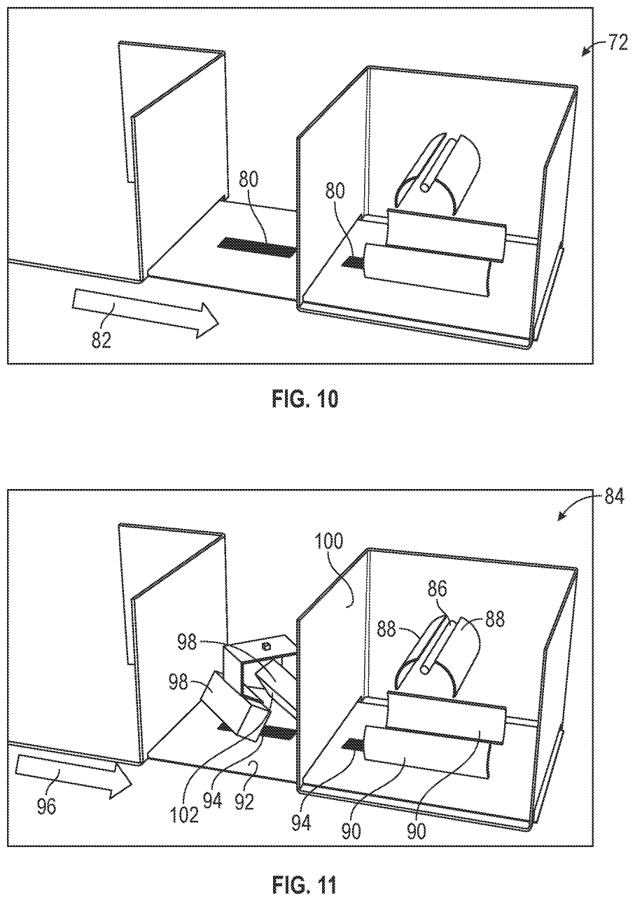

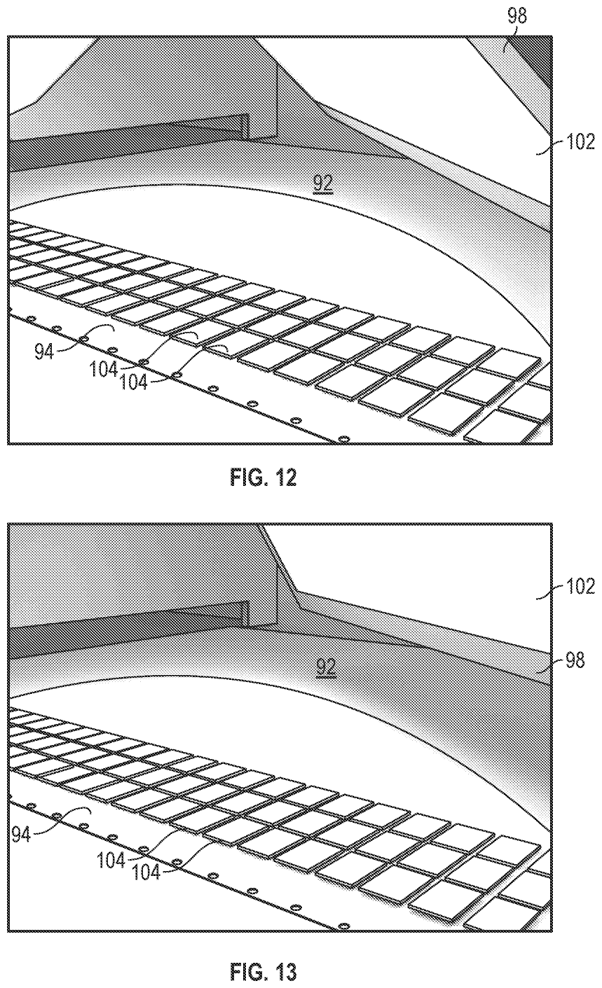

The angle of the LED panels 98 relative to the orientation of the package trays 94 serves to assist with providing an equal amount of light to all four sides of each image sensor package in the package tray 94 as the tray passed below the LED panels 98. The angle of the face 102 of the LED panels 98 to the plane formed by the conveyor 92 works to adjust the amount of shadowing experienced by the image sensor packages in the package tray 94 as they pass directly beneath the LED panels 98. Referring to FIG. 12, the shadowing of the image sensor packages 104 is illustrated when the angle of the face 102 is at 45 degrees. FIG. 13 illustrates the shadowing when the angle of the face 102 is at 30 degrees. It can be observed that the shadowing is reduced or the UV radiation exposure experienced by the image sensor packages 104 is improved in the implementation where the angle of the face 102 is at 45 degrees.

The electromagnetic irradiation system 84 implementation illustrated in FIG. 11 includes two LED panels 98. However, in other implementations, only one LED panel may be employed, or more than two LED panels could be utilized, each angled at a different position relative to the package tray orientation on the conveyor. Where more than one LED panel is utilized, in some implementations the face of each LED panel may be angled at the same angle relative to the plane formed by the conveyor. In other implementations, the face of each LED panel may be angled at a different angle relative to the plane formed by the conveyor. In yet other implementations, groups of two or more LED panels may be oriented at the same angle relative to the plane formed by the conveyor while other group(s) of two or more LED panels may be oriented at a different angle. Also, the various LED panels may be supported using multiple supports located along the length of the conveyor rather than a single support as illustrated in FIG. 11.

Since the electromagnetic radiation from a LED panel, though still diffusely emitted, can be more directional than that emitted by the bulb because of the effects of the lenses and reflectors associated with each LED, the net intensity of electromagnetic radiation experienced by the adhesive material of each image sensor package in a given amount of time can be significantly increased. Because of this, the ability of the system 84 to accomplish a uniform UV cure process with each image sensor package in each package tray can be increased. In various implementations, the location of the LED panels along the conveyor may be after the bulb portion or both before and after the bulb portion. Finally, while the electromagnetic irradiation system 84 in FIG. 11 is illustrated as including the combination of a bulb portion and at least one LED panel, in some implementations, only LED panel(s) may be employed in any of the various combinations disclosed herein and no bulb portion may be included. A wide variety of implementations and combinations may be constructed using the principles disclosed herein.

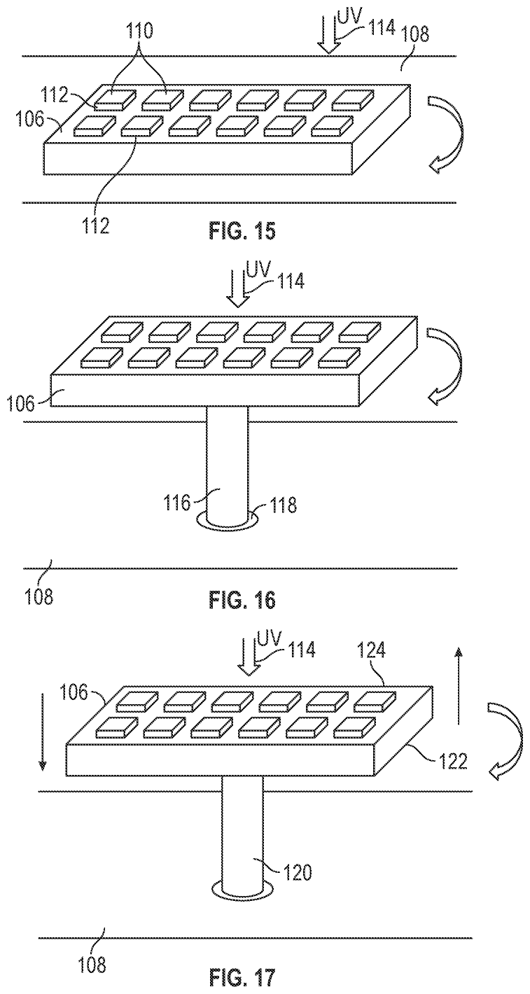

Either in combination with bulb+LED panel electromagnetic irradiation systems or with bulb only or LED panel only electromagnetic irradiation systems, various systems for rotating the position of package trays on the conveyor may be utilized. Referring to FIG. 15, an implementation of a package tray 106 is illustrated resting on conveyor 108. Package tray 106 is currently holding image sensor packages 110 in a plurality of openings 112 in the package tray 106. Each of the image sensor packages 110 include an adhesive material like any disclosed in this document that is used to couple an optically transmissive lid to an image sensor die included in the package according to any of the designs disclosed in this document. As illustrated in FIG. 15, the package tray 106 is currently being rotated clockwise on the conveyor 108 under UV irradiation 114 which may be generated by any UV irradiation source disclosed in this document. The rotation of the package tray 106 may be carried out in a variety of ways. For example, a magnetic or magnetizable portion may be included in/on the package tray 106 and a corresponding magnetic bar or other structure may be rotated beneath the package tray 106 while magnetically coupled to the magnetic or magnetizable portion of the package tray. In other implementations, a section of the conveyor 108 may be rotatable within the material of the conveyor using a chuck or other system for engaging the rotatable section located beneath the conveyor. In yet other implementations, arms/projections/pins may be extended from structures on one or both sides of the conveyor and used to sequentially rotate the package tray 106 in a desired location. In such implementations, the package tray may be removably and rotatably coupled to the conveyor using a pin or brad to assist with the package tray remaining in a centered location on the conveyor. In yet other implementations, a shaft may extend up through an opening in the conveyor at the location where the UV irradiation is taking place and the end of the shaft may engage with a structure/opening/mechanism in/on the package tray 106. The shaft may then be rotated in a desired direction during the irradiation process and then the end disengaged from the package tray 106 and retracted below the level of the conveyor. In yet other implementations, pneumatic jets could be utilized to rotate the package tray on the conveyor. Many possible mechanical and pneumatic mechanisms and systems could be employed to rotate the package tray 106.

The rotation of the package tray 106 under the UV irradiation serves to, for example, reduce/eliminate shadowing effects caused by directional UV irradiation directed from secondary mirrors like those in the previously describe irradiation systems as the image sensor packages now can have their sidewalls irradiated uniformly by averaged exposure caused by the speed and time of irradiation. Similarly, where LED panel sources are used, the ability to rotate the package tray beneath the LED panel source may also improve the time averaged dose of UV light provided to each image sensor package in the package tray. By so doing, the UV cure of the adhesive material achieved by each package is improved on all four sides of the image sensor packages.

Referring to FIG. 16, the package tray 106 is illustrated here in an elevated position having been lifted up by shaft 116 from the surface of the conveyor 108 through opening 118 in the material of the conveyor 108. In this position, at a desired height, the shaft 116 is illustrated rotating the package tray 106 in a clockwise direction. The height that the shaft 116 lifts the package tray 106 may be determined by various factors, including, by non-limiting example, an optimized optical position in an electromagnetic irradiation system based on ray tracing analysis, a desired location based on temperature analysis of an electromagnetic irradiation system, any combination thereof, or any other factor that affects the UV cure process. In particular implementations, raising the package tray 106 may assist with keeping the package tray 106 cooler to reduce the amount of thermal curing taking place during the UV cure process of the adhesive material of the image sensor packages. The rotation of the package tray 106 may produce any of the aforementioned effects with respect to time averaging of UV exposure of the sidewalls of the image sensor packages by UV light source 114. In the various implementations like those of FIG. 16, the end of the shaft may be coupled to the package tray 106 using variety of coupling mechanisms, including, by non-limiting example, magnetic, releasable latches, pins, clamps, friction fit, or any other end-on attachment system or mechanism.

In other implementations that utilize a raised position for the package tray 106, referring to FIG. 17, the shaft 120 may be configured to move the package tray 106 in more than just an X/Y plane above a plane formed by the conveyor. As indicated in FIG. 17, in addition to rotating in the X/Y plane, the shaft 120 is designed to rotate while adjusting a tilt of the package along a shortest axis 122 of the package tray 106, adjusting a tilt of the package tray 106 along a longest axis 124 of the package tray 106, or any combination thereof. In this way, the pitch and/or yaw of the package tray 106 are altered. In some implementations, only the pitch and/or yaw may be adjusted during the electromagnetic irradiation (here using UV light 114) and no rotation may be carried out. The ability to adjust the tilt of the package tray during or without rotation aids in exposing the sidewalls of the image sensor packages and the adhesive material to electromagnetic radiation that is directed in a particular direction without involving any movement of the electromagnetic radiation source or adjustment of the rays of radiation being provided by the apparatus.

The various shaft implementations may utilize any of the previously mentioned mechanisms for coupling the end of the shaft to the package tray along with additional mechanisms for adjusting the tilt which may include, by non-limiting example, movable cables, movable lifting shafts, one or more motors, or any other system or mechanism for changing the tilt either during or without rotation of the shaft 120. A wide variety of implementations may be formed using the principles disclosed herein.

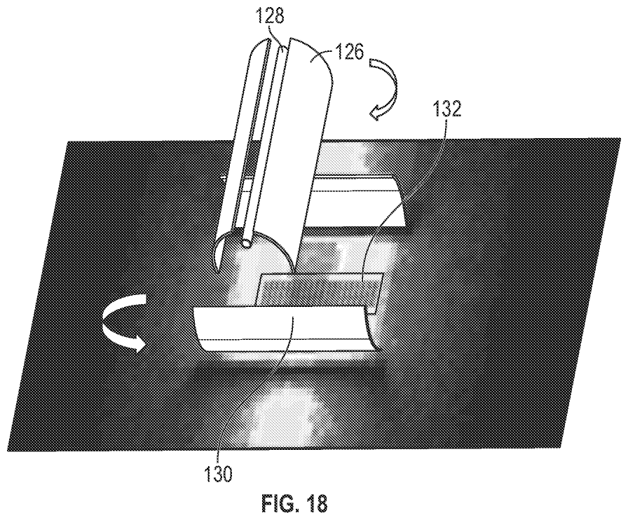

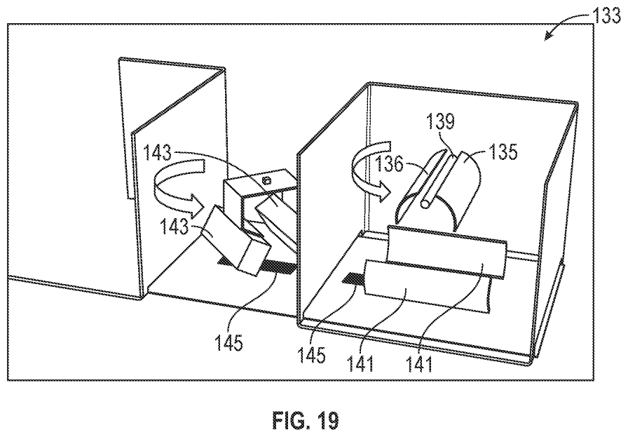

In the various implementations previously described, referring to FIGS. 18 and 19, components of the electromagnetic irradiation system/source may also be rotated while the position of the package tray is moved using any of the previously described systems. In FIG. 18, the rotation of the primary reflectors 126 and bulb 128 in a clockwise direction in combination with rotation of the secondary reflectors 130 in a counterclockwise direction is illustrated above the package tray 132. The effect of the rotation is to change the position of the maximum area of irradiation as represented by the heat map over the package tray 132 as the package tray 132 passes through the system. While the counter rotation of both primary and second reflectors is illustrated in FIG. 18, both may be rotated in the same direction or only the primary reflectors 126 and bulb 128 or only the secondary reflectors 130 may be rotated in various implementations.

In the implementation of FIG. 19, an electromagnetic irradiation system 133 is illustrated where the primary reflectors 135 and bulb 139 rotate while the secondary reflectors 141 do not rotate and the LED panels 143 also rotate above the package trays 145. In this way a time averaging effect can be achieved in addition to the rotation/tilt of the package trays below either or both irradiation sources to achieve a better and more uniform UV cure of the adhesive material of the packages. While rotation of both the primary reflectors 135 and the LED panels 143 is illustrated in FIG. 19, only the LED panels 143 may be rotated or only the primary reflectors 135 and/or secondary reflectors 141 may be rotated in other implementations. Also, in various implementations, no rotation or tilt of the package trays may be carried out while the reflectors/LED panels are being rotated where the time averaging effect of the irradiation is accomplished by reflector/LED panel rotation rather than the movement of the package trays. A wide variety of implementations may be constructed using the principles disclosed herein.

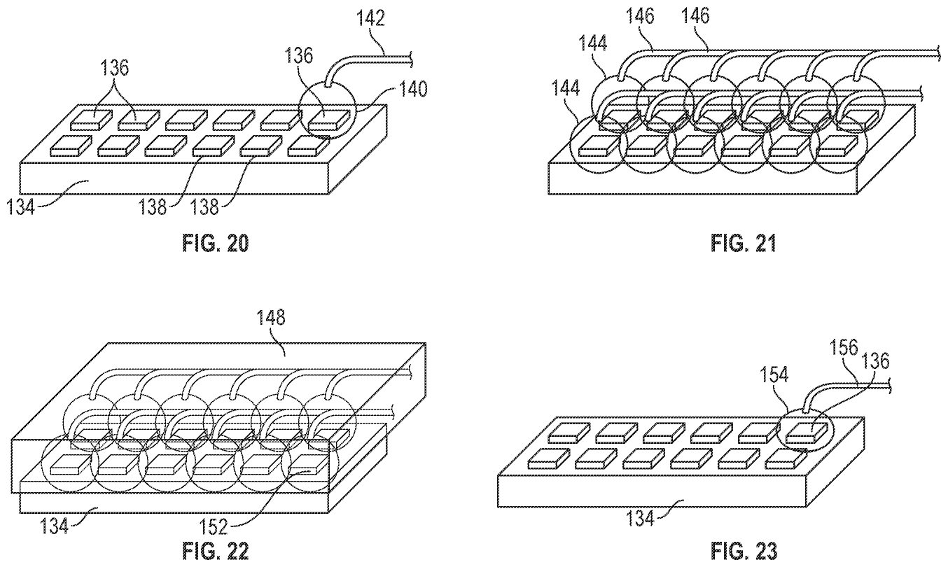

The foregoing implementations have involved use of an electromagnetic irradiation source into/under which package trays move to receive electromagnetic radiation during an adhesive material curing process. In other processes and systems, however, the light may be directed to each image sensor package in the package tray individually. Referring to FIG. 20, a package tray 134 is illustrated that includes a plurality of image sensor packages 136 placed into openings 138 in the package tray 134. Spherical enclosure 140 (shown in see-through view) optically coupled with fiber optic cable 142 that is optically coupled with an electromagnetic radiation source (not shown in FIG. 20) is placed over image sensor package 136. The bottom edge of the spherical enclosure 140 rests on the surface of the package tray 134 to form a substantial light-tight enclosure. The internal surface of the spherical enclosure 140 that surrounds the image sensor package 136 is substantially reflective of the particular wavelength of electromagnetic radiation carried by the fiber optic cable 142 (in this case UV radiation). Because the internal surface of the spherical enclosure 140 is reflective, UV radiation that is not absorbed by the material of the image sensor package 136 continues to reflect around the interior of the spherical enclosure until it is absorbed. This ability to keep internally reflecting the UV radiation inside the spherical closure 140 greatly increases the likelihood UV radiation will encounter the adhesive material and begin the UV curing reaction in the material and can also reduce the time required to achieve a given amount of UV radiation exposure, thus reducing the total radiation exposure time needed for each unit, since the units are now treated individually rather than collectively in a time averaged fashion as in previous implementations.

Once the image sensor package 136 has been exposed for a sufficient/predetermined period of time, the spherical enclosure 140 can be removed and placed over the next image sensor package. The electromagnetic radiation source can be shut off or left on during this transition depending on the particular implementation. This one-at-a-time processing may be sufficiently fast in various implementations, but faster processing could be achieved using an apparatus like that illustrated in FIG. 21, where a plurality of spherical enclosures 144 each coupled to a plurality of fiber optic cables 146 coupled to the same or multiple electromagnetic radiation sources is employed. Here, the radiation exposure process can be carried on simultaneously after the spherical enclosures 144 are placed over the image sensor packages 136, then raised after the proper/predetermined period of time and lowered over the next set of image sensor devices in the next package tray.

Simultaneous processing with electromagnetic radiation can also be carried out where the spherical enclosures are formed into the same piece of material as in the see through version of FIG. 22, where a set of spherical enclosures 152 are formed in the material of solid 148 to which a plurality of fiber optic cables 150 are attached, each fiber optic cable attached to each spherical enclosure. The set of spherical enclosures 152 are sized and positioned to fit over the plurality of image sensor packages in the package tray 134 similar to the array of spherical enclosures 144 illustrated in FIG. 21. In this way, the solid 148 can be placed over each package tray 134 and provide irradiation to all of the image sensor packages in the package tray 134 for a proper/predetermined period of time before being lifted away from the package tray and positioned over the next package tray. Various sizes and configures of solids may be employed for different image sensor package sizes or package tray sizes and processing of multiple package trays at a time could be enabled using a single electromagnetic radiation source or several sources with this apparatus and method implementation.

Up to this point, the use of spherical enclosures has been illustrated, but enclosures of other solid shapes could be employed as well, such as, by non-limiting example, semi-spherical, ellipsoidal, triangular, pyramidal, rectangular, or any other solid shape that provides the desired reflection and/or electromagnetic radiation focusing effect on the image sensor package sidewalls. FIG. 23 illustrates an ellipsoidal enclosure 154 shown in partial see through view with fiber optic cable 156 coupled thereto placed over image sensor package 136 in package tray 134. The shape of the ellipsoidal enclosure 154 may be configured to achieve the desired reflective/focusing effect on the sidewalls of the image sensor package 136 to ensure the adhesive material curing takes place in a desired period of time or in a desired measure. The reflective/focusing effect may work to increase the curing effect and thus reduce the processing time needed per image sensor package in some implementations.

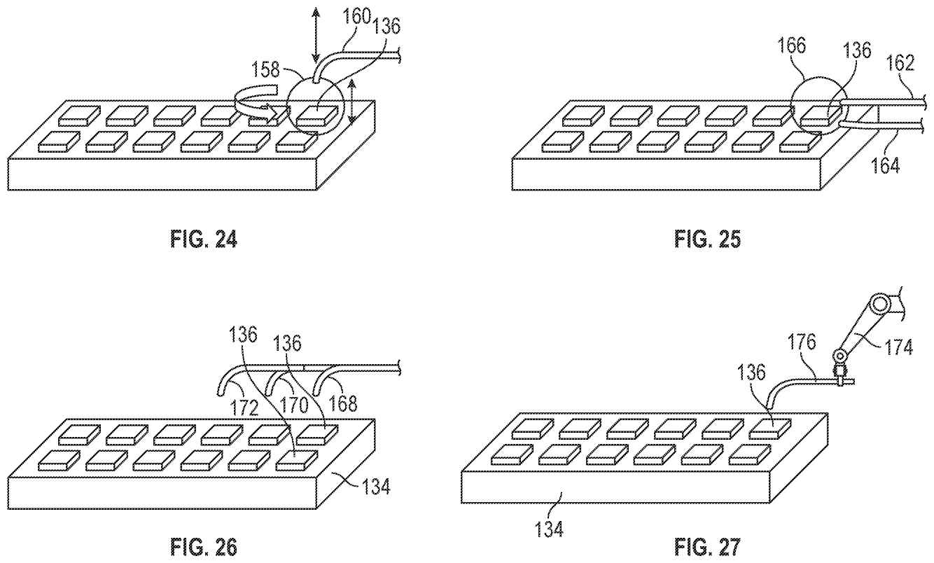

The foregoing implementations have utilized static placement of the enclosures over the image sensor packages for a period of time. However, as illustrated in FIG. 24, the enclosures and/or the fiber optic cable may be moved during processing to facilitate desired curing effects of the adhesive material and/or speed up processing time. In FIG. 24, spherical enclosure 158 is illustrated as being able to be rotated after placement over image sensor package 136 as well as being able to be moved/translated upwardly or downwardly during irradiation. Fiber optic cable 160 is also illustrated as being able to be inserted further into or moved out of the spherical enclosure 158 during irradiation to change the reflection pattern inside the spherical enclosure dynamically. In this implementation, the movement may be desired to create a certain radiation pattern on the sidewalls to facilitate the cure process in a certain direction in the adhesive material (inside-outside or outside-inside). Those implementations where the enclosure and/or the fiber optic cable can be moved/translated during irradiation may include where multiple enclosures are employed or where a solid that contains multiple enclosures is employed as well.

The foregoing implementations have employed a fiber optic cable connected to an electromagnetic radiation light source to provide electromagnetic irradiation. However, in the preceding or subsequent implementations that utilize a fiber optic cable, a fiber optic cable may not be used but a support with an electromagnetic radiation light source coupled to the end may be utilized instead. In these implementations, the electromagnetic light source may be an LED, group of LEDS, a bulb, or a group of bulbs like any disclosed herein. The support can then be moved around as described herein to carry out the curing operation through electromagnetic irradiation using any of the wavelengths disclosed herein.

The foregoing implementation have illustrated where a single fiber optic cable has been used for a corresponding enclosure. In various implementations, however, two or more fiber optic cables could be applied to each enclosure and used simultaneously or in sequence to provide electromagnetic radiation to the enclosure. Referring to FIG. 25, fiber optic cables 162, 164 are illustrated being optically coupled with spherical enclosure 166 at two different positions. Here, electromagnetic radiation from the same electromagnetic radiation source or different electromagnetic radiation sources could be supplied simultaneously or sequentially to the enclosure and to image sensor package 136. Where multiple fiber optic cables are employed, electromagnetic radiation of different wavelengths could be supplied to the enclosure as part of the cure operation in particular system and method implementations. While the use of two fiber optic cables 162, 164 is illustrated in FIG. 25 with a single spherical enclosure 166, multiple fiber optic cables could be coupled with any multiple enclosure implementation disclosed herein including those involving a solid.

The use of enclosures combined with fiber optic cables has been discussed thus far in this document. However, the use of fiber optic cables standing alone could be used to irradiate the sidewalls of the image sensor packages in either a single pass or multiple pass manner. Referring to FIG. 26, package tray 134 is illustrated with a plurality of image sensor packages 136 coupled thereto alongside fiber optic cables 168, 170, 172. In various implementations, fiber optic cables 168, 170, 172 could be coupled to the same electromagnetic radiation source or different sources. Where different electromagnetic radiation sources are employed, the wavelengths of the electromagnetic radiation being emitted by each fiber optic cable 168, 170, 172 may be different or the same. In this implementation, the ends of the fiber optic cables 168, 170, 172 may be directed at the sidewall or at a desired angle to the sidewall of the image sensor packages 136. Because in this implementation the use of fiber optic cables is used, the electromagnetic radiation source/electromagnetic radiation being supplied from the end of each fiber optic cable may be coherent and not just diffuse. The use of coherent light may further sharpen/focus the electromagnetic radiation being supplied to the sidewall and reduce the amount of exposure time needed to initiate the cure process with the adhesive material in each package.

As a way of assisting more of the fiber optic cables to traverse the sidewalls of all of the image sensor packages 136 in the package tray 134, mechanical supports may be used. Referring to FIG. 27, a robotic arm/mechanical arm 174 is illustrated holding fiber optic cable 176 in a desired position during irradiation of the sidewall of image sensor package 136. In this implementation, the robotic arm/mechanical arm 174 may move the end of the fiber optic cable 176 around the sidewalls/perimeter of each image sensor package 136 to complete the electromagnetic exposure process and complete the cure process. While the use of a single fiber optic cable 176 and single robotic arm/mechanical arm 174 is illustrate in FIG. 27, more than one fiber optic cable attached to a single robotic arm/mechanical arm could be used as could multiple robotic arms/mechanical arms each attached to a single fiber optic cable in various implementations. In all of the foregoing implementations involving fiber optic cable direct exposure, movement of the package tray along the conveyor may also be employed to aid in irradiating the various image sensor packages either alone or in combination with a robotic arm(s)/mechanical arm(s).

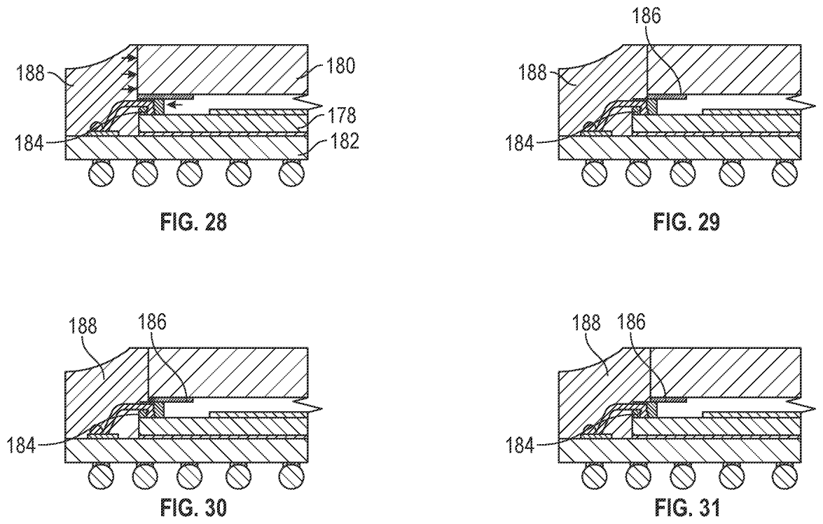

The foregoing system and method implementations have focused on ways to increase/focus/direct electromagnetic radiation into the adhesive material while it is shaded by the black mask material with an optically transmissive cover that has a larger perimeter than the perimeter of the image sensor die itself. In other system and method implementations, the perimeter of the optically transmissive cover may be adjusted to a desired dimension relative to a perimeter of the image sensor die. By changing the length of the perimeter of the optically transmissive cover, the amount of overhang of the optically transmissive cover can adjusted for the same perimeter size of the image sensor die. This technique can be employed for image sensors that include an air gap or are gapless image sensors (as can the other method implementations and irradiation systems disclosed in this document). Referring to FIG. 28, a cross sectional view of a portion of a sidewall of an image sensor package is illustrated which includes image sensor die 178 coupled to substrate 182 with optically transmissive cover 180 coupled to the image sensor die 178 through adhesive material 184. As previously discussed, moving the position of the adhesive material closer to or up to the edge of the image sensor die 178 has been demonstrated to reduce failures resulting from insufficient UV curing of the adhesive material. As the other arrows in FIG. 28 indicate, however, is that the overhang of the optically transmissive cover 180 can be reduced. The overhang of the optically transmissive covers over the edge of the optically transmissive cover illustrated thus far in this document has been about 100 microns. In particular implementations, this may be reduced to 50 microns or less. In some implementations, the overhang can be reduced to 0 microns or less as illustrated in FIG. 28. In such implementations, the length of the perimeter of the optically transmissive cover 180 and the length of the perimeter of the image sensor die 178 may be substantially the same to achieve no overhang.

In other implementations, the overhang can be reduced to—5 microns or less, meaning that the length of the perimeter of the optically transmissive cover 180 is now smaller than the length of the perimeter of the image sensor die 178. An example of an implementation where the overhang is half the width of the adhesive material 184 (negative overhang) is illustrated in FIG. 29. An example of an implementation where the overlap is more than half of the width of the adhesive material 184 (still negative overhang) is illustrated in FIG. 30. An example of an implementation where the overhang is less than half of the width of the adhesive material 184 (negative overhang) is illustrated in FIG. 31. As illustrated in FIGS. 29-31, the effect of negative overhang is that electromagnetic radiation applied directly downwardly and at a slight angle into the image sensor can now directly reach the adhesive material 184 and begin the curing process because the black mask no longer completely shadows the adhesive material 184. Because optically opaque mold compound 188 is then applied over the sidewall of the image sensor die 178 and the sidewall of the optically transmissive cover 180, after the curing process is completed for the adhesive material, reflective effect from the bond wires and the bond pads can still be prevented even in the negative overhang cases. In some implementations, the reduction of the overlap can result in cost savings.

In various implementations, the overhang on each side of the image sensor die may be the same; in other implementations, however, the overhang on at least one side of the image sensor die may be different from the overhang on at least one other side. In such implementations, changes in the placement of the adhesive material adjacent to the image sensor die like those previously discussed in this document may be employed to help ensure adequate curing even when the overhang on one side is greater than the overhang on another side of the image sensor.

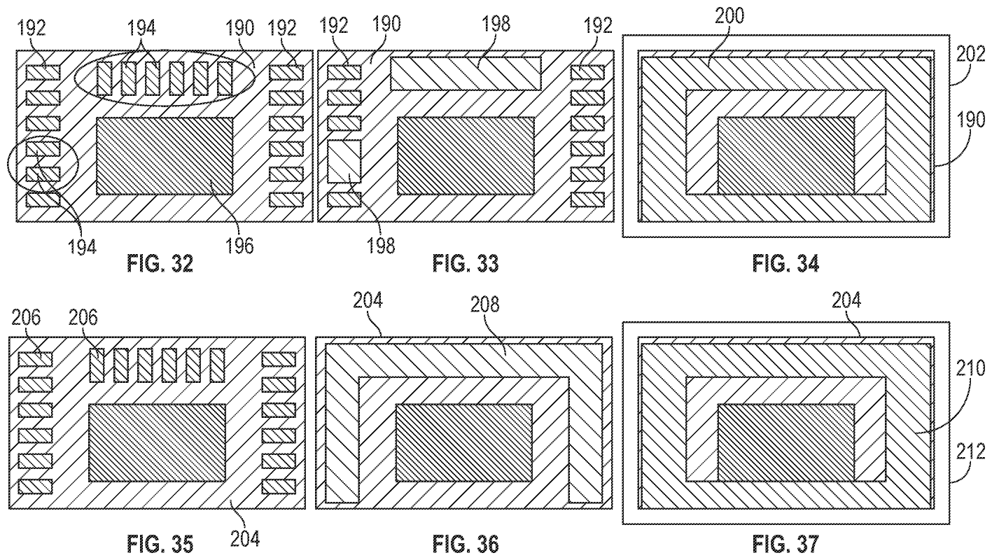

Since one of the issues noted during reliability testing is corrosion of the bond pad/wire bond joint caused by mobile ions present in the uncured adhesive material, various method and system implementations may employ strategies to protect the material of the bond pads from contact with the adhesive material. Referring to FIG. 32, an implementation of an image sensor die 190 from a top down view is illustrated. Here, the image sensor die 190 includes bond pads 192, 194 where bond pads 194 have a higher operating voltage than the remaining bond pads 192. Pixel array 196 is also visible in this view. In this view, all of the bond pads 192, 194 have been bonded to a bond wire via a wire bond but these are not shown in FIGS. 32-37 for more easier illustration.

As previously discussed, the higher the operating voltage of a bond pad/wire bond combination, the more readily corrosion occurs due to migration of free ions in the uncured adhesive material. Referring to FIG. 33, the image sensor die 190 from FIG. 32 is illustrated following application of a protective layer 198 over the bond pads 194 that have a higher operating voltage but not over the remaining bond pads 192. The protective layer 198 is applied after the wire bond with the bond wire has been formed to the bond pads 192. The protective layer 198 may be formed of various material, including, by non-limiting example, an encapsulant, a mold compound, an acrylic, an acrylic polymer, an epoxy compound, or any other organic compound that has the ability to form a seal with the adhesive material. In various implementations, the protective layer 198 may be cured using a separate cure process which may involve heating, electromagnetic irradiation, or both. Referring to FIG. 34, with the protective layer 198 in place, in various method implementations, adhesive material 200 is then applied adjacent to the edges of the image sensor die 190 followed by coupling of the optically transmissive cover 202 (shown in see-through view of the black mask layer thereon) over the image sensor die 190 and then any of the previously mentioned methods and systems for curing the adhesive material 200 can be carried out. Because of the presence of the protective layer 198, however, none or substantially none of the mobile ions present in the uncured or partially cured adhesive material 200 can reach the material of the wire bond and/or the bond pads 194. The ability of the protective layer 198 to break the corrosion pathway for the bond pads and wire bond may, in itself, create a situation where various of the techniques disclosed herein for improving the likelihood/consistency of curing at the UV curing process may not be needed.

Referring to FIG. 35, another image sensor die 204 with bond pads 206 is illustrated. As previously discussed, the bond wires have previously been wirebonded to the bond pads 206 but are not shown in FIG. 35 for easier illustration. In the method implementation illustrated in FIGS. 35-37, instead of treating one or more of the bond pads differently by coating one or more of the bond pads with the protective coating, all of the bond pads 206 are covered by a protective layer 208 as illustrated in FIG. 36. This protective layer 208 may be any disclosed in this document and may be applied and cured using any method disclosed in this document. FIG. 37 illustrates the image sensor die 204 following application of adhesive material 210 over the protective layer 208 covering the bond pads 206 and dropping/placing of the optically transmissive cover 212 (shown in see through of the black mask material) onto the adhesive material 210. Any of the previously discussed methods of curing the adhesive material 210 may then be employed. In this implementation, because the protective layer 208 has been applied over all of the bond pads 206, application of the adhesive material 210 may be easier because of the greater uniformity of the height of the material over the semiconductor die 204 and bond pads 206. This greater uniformity may assist with ensuring a successful bond between the adhesive material 210 and the protective layer 208.

The various image sensor die that employ protective layers may employ various implementations of a method of applying a protective layer. The method includes providing an image sensor die that includes a plurality of bond pads and bonding a plurality of bond wires coupled to the plurality of bond pads. The method also includes applying a protective layer like any disclosed herein over the plurality of bond wires and the plurality of bond pads. The method also includes curing the protective layer and then applying an adhesive material directly over the protective layer. The method then includes attaching an optically transmissive cover to the adhesive material and curing the adhesive material. As previously discussed, the optically transmissive cover includes a black mask material applied around the perimeter of the optically transmissive cover which may be any configuration disclosed herein. The curing process for the adhesive material may employ UV light and/or thermal cure like any method disclosed in this document.

In some implementations, the material of the protective layer is the same material as the adhesive material itself (which may be any adhesive material disclosed herein). Because the protective layer does not have to be as thick as the adhesive material as it does not need to support a gap between the optically transmissive cover and the image sensor die. Also, the protective layer is formed prior to coupling of the optically transmissive cover so no black mask shadowing prevents irradiation treatment. Furthermore, given the thinner nature of the protective layer, no issues with thermal curing would be encountered during the thermal treatment of the protective layer material. Thus, despite the material of the protective layer being the same as that of the adhesive material, since the protective layer can be fully cured, any halogen ions present in the protective layer are no longer mobile, and so corrosion still be prevented.

The preceding discussion regarding corrosion of the wire bond and bond pad indicated that the ability of halogen ions including chlorine in the not fully cured adhesive material permitted the formation of a galvanic cell that facilitated corrosion of the bond pad and/or wire bond. Since the wire bond is composed of a combination of the materials of the bond pad and the bond wire, changes to the materials of the bond wire and/or the bond pad can be used in various image sensor die to eliminate or significantly reduce the likelihood of corrosion by altering the metals involved. Various over pad metallizations are discussed in this document that change the metals and thus the electrical potential differences between the materials of the bond pad and the bond wire.

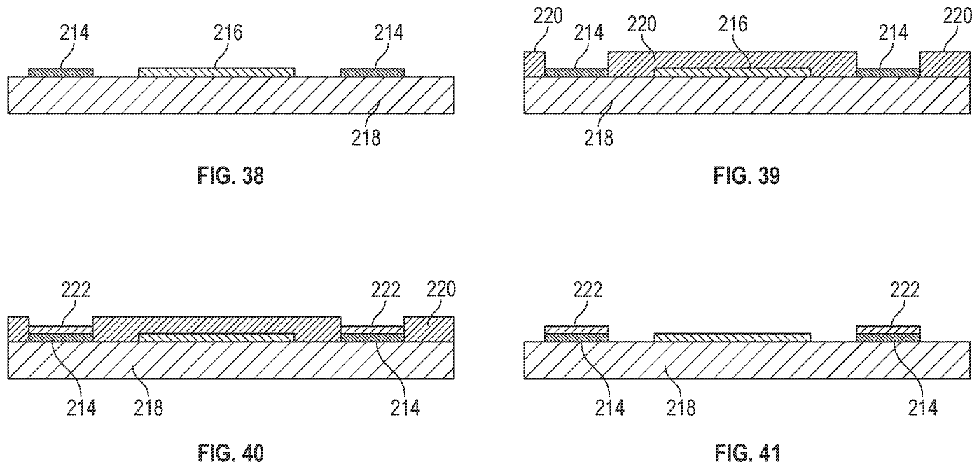

Referring to FIG. 38, an implementation of an image sensor die 218 in a simplified view showing bond pads 214 and pixel array 216 is illustrated. The bond pads 214 in FIG. 38 are made of one or more layers of one or more materials which, in particular implementations, may include aluminum. FIG. 39 illustrates the image sensor die 218 following formation of a patterned layer 220 that covers the pixel array 216 while leaving the bond pads 214 exposed. The patterned layer may be a photodefinable material like a photoresist or polyimide or may be applied using a stencil using a squeegee or screen printing process in various implementations. FIG. 40 illustrates the image sensor die 218 following formation of over pad layers 222 over bond pads 214 using the patterned layer 220 to protect the pixel array 216. The over pad layers may include, by non-limiting example, nickel/gold, nickel/palladium/gold, nickel/palladium, copper, copper/nickel/gold, any combination thereof, or other metals/metal stacks that would prevent corrosion of the material of the bond pads by ions in the adhesive material. In various implementations, the over pad layer may be a single layer in the form of an alloy of the various metals or may be composed of multiple layers of the metals deposited on top of the other. Electroplating, electroless plating, or sputtering may be used to form the over pad layer or the various sublayers within it. Where vacuum operations like sputtering are employed, measures to ensure full curing/drying of the material of the patterned layer 220 may be implemented to prevent flaking, peeling, outgassing, or bubbling of the pattern layer 220.

FIG. 41 illustrates the image sensor die 218 following removal of the patterned layer 220 using any process capable of removing the material of the patterned layer (solvent stripping, ashing, etching, dissolving, etc.). Here the over pad layers 222 are now ready for wirebonding to a bond wire. In the various method implementations, the over pad layers 222 may be formed prior to formation/application of a color filter array over the pixel array 216 to help limit contamination. However, in some implementations, the color filter array can be formed first and the patterned layer 220 is used to protect it during the formation process of the over pad layers.

In various system and method implementations, the material of the bond wire may be selected to help assist with reducing the likelihood of corrosion. Where gold wire is used in combination with an aluminum pad, the use of 2N gold wire (99% pure) rather than 4N gold wire (99.99% pure) can assist with reducing the likelihood of corrosion. In other implementations, other bond wire materials may include, by non-limiting example, 99.99% copper wire, palladium coated copper wire, plated copper wire, silver wire, any combination thereof, or other metals/metal alloys/coated metals capable of being drawn into wire and which reduce the likelihood of corrosion with the particular material(s) of the bond pad. In some implementations, changing the material of the bond wire may be sufficient to prevent corrosion without the use of an over pad layer.

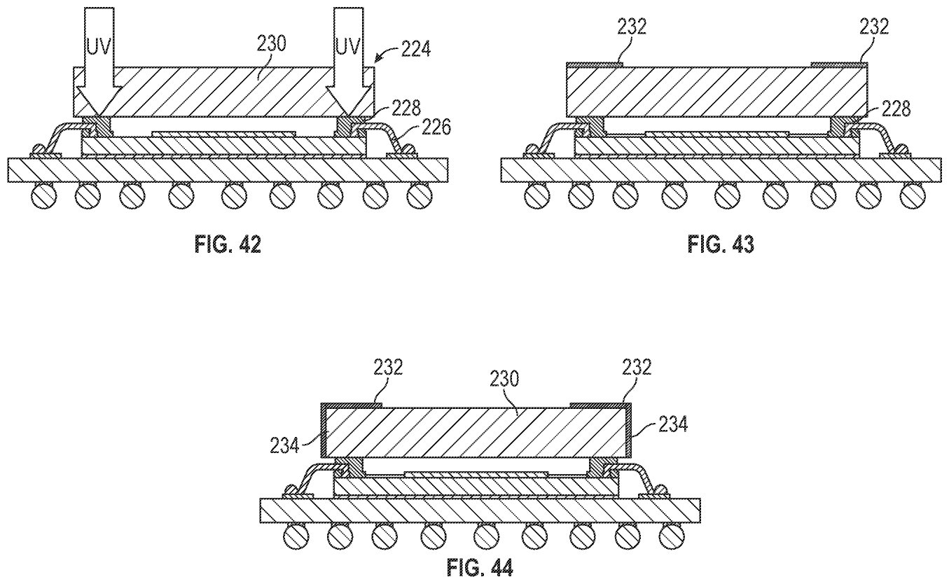

The various optically transmissive cover implementations disclosed herein have been disclosed thus far to include the black mask on the largest planar side of the optically transmissive cover that faces the image sensor die. It is possible, however, to apply the black mask material to at least the largest planar side of the optically transmissive cover opposite of the side that faces the image sensor die. Referring to FIG. 42, an implementation of an image sensor package 224 is illustrated after bonding of bond wires 226 to bond pads to form wire bonds. Adhesive material 228 has been applied over the bond wires 226 and bond pads and optically transmissive cover 230 has been coupled over/applied to the adhesive material 228 using any of the methods disclosed herein. Any of the material types disclosed in this document may be used for the adhesive material 228 in various implementations. As illustrated in FIG. 42, UV light irradiation is now being applied to the image sensor package 224 during a UV cure process of the adhesive layer 228.

Referring to FIG. 43, the image sensor package 224 is illustrated following application of a black mask layer 232 around the perimeter of the optically transmissive cover 230. In various method implementations, the application of the black mask layer 232 may take place prior to or following thermal curing of the adhesive layer 228. In other implementations, the UV cure process fully cures the adhesive material 228; in others it may only partially cure the adhesive material 228 as described herein. Since the black mask layer 232 was not present until after the UV cure process has been completed, it does not provide any shadowing or blocking effect and thus the use of the electromagnetic irradiation systems that provide UV light directly down onto the image sensor package 224 may be sufficient to complete the UV cure process without problems of areas of insufficiently UV cured adhesive material. In some implementations where the material of the black mask layer 232 is thermally cured, the black mask layer 232 and the adhesive layer 228 can be thermally cured at the same time following application of the black mask layer 232.

Referring to FIG. 44, in various method implementations, the black mask material can be applied over the sidewalls 234 as well as the upper largest planar surface of the optically transmissive cover 230. In this way, any incident light on the sidewalls of the optically transmissive cover can be blocked if the edge of the optically transmissive cover extends above a mold compound subsequently applied to the image sensor package 224. In some implementations, the black mask material may not be applied to the optically transmissive cover until after the mold compound is applied and thus after the adhesive material is fully cured. In such implementations, the location of the black mask material can be directly aligned with the location of the pixel array in the as-assembled package, which can ensure greater accuracy of the position. This may also entirely eliminate any position variation of the black mask layer due to differences in ultimate placement of the optically transmissive cover itself which results in the black mask layer first process.

In various implementations the black mask material utilized in these system and method implementations (and in the other system and method implementations in this document) may be a black mask material manufactured by Platinum Optics Technology Inc of Taipei, Taiwan; Nippon Electric Glass, Ltd. of Otsu, Japan; Zhejiang Quartz Crystal Optoelectronic Technology Co., Ltd. of Taizhou City, China; Kyocera Corporation of Kyoto, Japan; or Viavi Solutions, of Chandler, Arizona. The black mask material may be cured using electromagnetic radiation, UV light, thermal energy, or any combination thereof in various implementations. In various implementations, because the black mask layer is formed on the upper surface of the glass, a thinner glass material may be used because the black mask layer is more efficient than mold compound in blocking incident electromagnetic radiation from different angles. Many different method and structural variations may be created using the principles disclosed in this document.

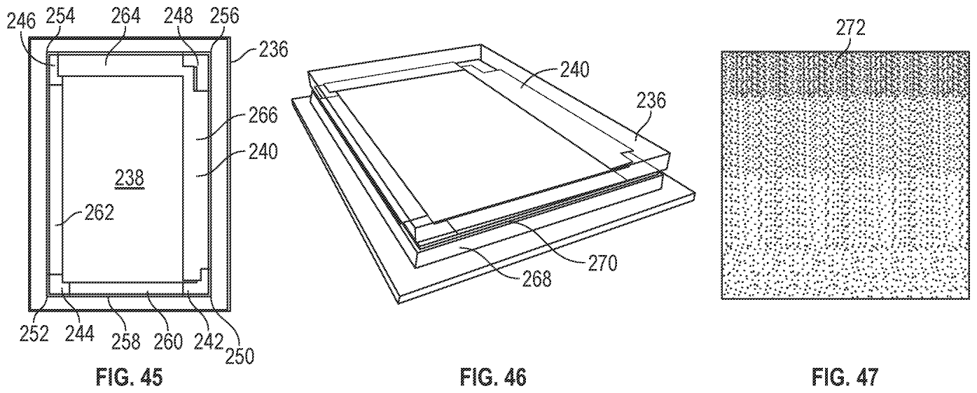

In the various image sensor packages disclosed in this document, location specific failures during reliability testing have been noted due to corrosion effects and others resulting from incomplete curing of the adhesive material of the image sensor package. In various implementations, the locations of these failures can be in the corner areas of the image sensor die. Thus, leaving/creating locations in the black mask layer where openings exist to allow for full penetration of the electromagnetic radiation during an electromagnetic cure process may be utilized in various structure and method implementations. Referring to FIG. 45, an implementation of an optically transmissive cover 236 is illustrated from a top-down view along with the outline of a pixel array 238 showing the overlap of a black mask layer 240 that has a mask pattern that includes corner openings 242, 244, 246, 248 therein that expose all four corners 250, 252, 254, 256 of the perimeter 258 of the optically transmissive cover 236. Because only the corners 250, 252, 254, 256 of the optically transmissive cover 236 are exposed, scattered light is less likely to reach the pixel array 238.

By inspection, the mask pattern includes four segments 260, 262, 264, 266 of which only segments 264 and 266 are attached with black mask material. The black mask material may be any disclosed in this document in various implementations. Note that each of the four segments have a different width measured between the edge of the optically transmissive cover 236 to the inner edge of the segments. While two of the segments 264 and 266 are still attached, in various implementations, none of the segments could be attached or all of the segments could still be attached. The purpose of the attachment portion of the segments to assist with blocking scattered light while still allowing the region of the adhesive material to be exposed to electromagnetic radiation to assist with curing the adhesive material at the radiation cure step of the assembly process.

Referring to FIG. 46, the black mask layer 240 is illustrated in perspective view coupled to the largest planar side of the optically transmissive cover 236 that faces the image sensor die 268. Thus the black mask layer 240 is in direct contact with the adhesive material 270 in this implementation. In other implementations, the black mask layer 240 may be coupled to the opposite largest planar side of the optically transmissive cover 236, or the one that opposes the side facing the image sensor die 268. In such implementations, the methods of forming the black mask layer 240 and the characteristics of the optically transmissive cover 236 may be any previously described in this document for similarly oriented black mask layers.

While the black mask layer has been illustrated as exposing the corners 250, 252, 254, 256 of the optically transmissive cover 236, one or more additional portions of the black mask layer may contain openings/cutouts that expose additional portions of the optically transmissive cover. These one or more openings/cutouts may be located over bond pads that operate at higher voltages than other bond pads or over bond pads where historical failures have been noted over time as a way of assisting with improving curing of the adhesive material in those areas. A wide variety of mask patterns may be constructed using the principles disclosed herein.

Referring to FIG. 47, an implementation of a stipple pattern 272 is illustrated. While the black mask layers disclosed in this document up to this point have included fully solid patterns (with the exception of the openings previously discussed), the black mask layer may actually be applied in such a way as to create a stipple pattern. This stipple pattern 272 has the effect of absorbing a certain percentage of the scattered light that encounters the material of the stipple pattern. As illustrated in FIG. 47, the stipple pattern may gradate from a dense side to a light side. In other implementations, however, the stipple pattern may be a single uniform pattern. The use of the stippling pattern may help with curing of the adhesive material because sufficient time can be given to the image sensor packages in the electromagnetic irradiation system to ensure that sufficient electromagnetic radiation has been provided to the adhesive material to reach a desired degree of cure, even where the stipple pattern is gradated. While the blocking performance of the black mask layer may be reduced compared to a solid pattern, for the particular image sensor package, the degree of blocking may be sufficient to reach a desired level of performance/flare avoidance in various implementations.

While the use of a stipple pattern has been illustrated in FIG. 47, the use of a half tone pattern where the position of the dots of the pattern is uniformly distributed across the pattern, but the size of each dot is varied in a direction across the pattern to cause a visual fading effect. The use of halftone may involve the use of multiple dot shapes and overlapping of multiple dot shapes/dots to help create the pattern. Also, in half tone implementations, a color/absorption characteristic of the dot materials may be altered between dot types to create the desired electromagnetic absorption profile.

Forming the stipple pattern may involve spraying the material of the black mask layer directly onto the desired surface of the optically transmissive cover (side facing the image sensor die or the opposing side). In other method implementations, the stipple pattern may be sprayed onto a piece of tape or other translucent material and then applied to the desired surface of the optically transmissive cover. In yet other implementations, the stipple pattern may be lithographically patterned, etched, and the etched features then filled with an optically opaque material to form the desired stipple pattern.

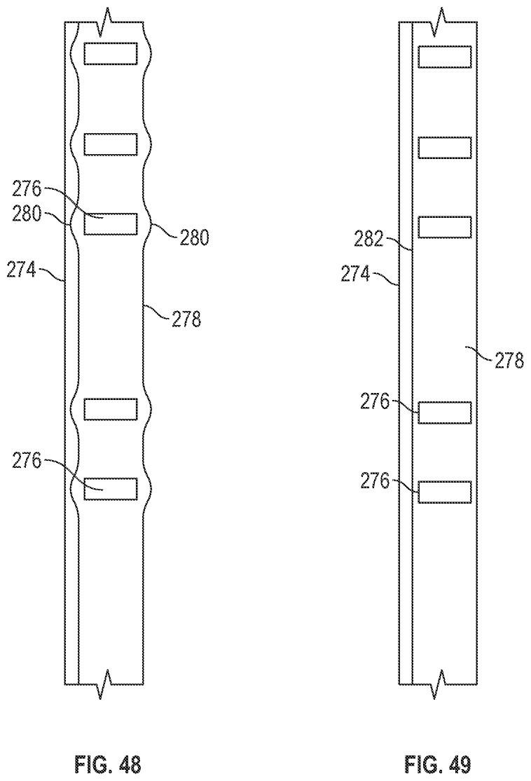

Previously, techniques for controlling the flow of adhesive material being dispensed onto an image sensor die over wirebonds and bond pads has been discussed. Referring to FIG. 48, an edge of an implementation of an image sensor die 274 is illustrated with a plurality of bond pads 276 arranged along the edge. While in various implementations, one or more of the bond pads 276 may each have a bond wire coupled thereto through a wire bond as disclosed herein, for the sake of easier illustration, the bond wires and wire bonds have been omitted in FIG. 48. Here, adhesive material 278 has been dispensed over the bond pads 276 and the resulting sidewall profile of the adhesive material in this top down view is now visible. As can be seen from inspection, the sidewall of the adhesive material bulges outwardly on both sides of the bead of adhesive material 278 at those locations 280 where the adhesive material crosses over the bond pads 276. This is because the volume of the bond pads 276 (and the bond wires and wire bond) displaces part of the dispenses volume of the adhesive material 278 causing it to flow away from the bond pads 276. In various methods of applying an adhesive material, the method includes driving a dispensing nozzle in an application path that applies the adhesive material 278 at the edge of the image sensor die 274 over the bond pads and bond wires to achieve a consistently straight sidewall edge 282 of the adhesive material 278 as illustrated in FIG. 49 of the adhesive material.

The creation of this consistently straight sidewall edge 282 may be accomplished in various method implementations in various ways previously discussed, including, by non-limiting example, varying a volume dispensed, varying a speed of dispense, varying a height of a dispensing nozzle, increasing a pressure applied to adhesive material through the dispensing nozzle, decreasing a pressure applied to the adhesive material through the dispensing nozzle, or any combination thereof. One of the effects of creating the consistently straight sidewall is that the resulting sidewall profile of the adhesive material is also substantially parallel with the sidewall/edge of the image sensor die 274. Those of ordinary skill in the art can use the principles disclosed herein to determine various operating parameters of the adhesive material dispensing system that can create the desired consistently straight sidewalls as the adhesive material 278 is dispensed over the bond pads 276 and corresponding bond wires and wire bonds.

In various other system and method implementations disclosed herein, the use of an adhesive material that is free of chlorine or other halogen ions may be employed. Such implementations of adhesive material work to eliminate the ions that participate in driving the corrosion reaction in non-fully cured adhesive material and the wire bonds/bond pads during operation of the device. In such implementations, the various systems and methods disclosed herein to ensure sufficient UV curing may be reduced or eliminated as ordinary UV cure processing may be sufficient to achieve the UV cure needed.

In places where the description above refers to particular implementations of wire-in-dam packages and related methods and implementing components, sub-components, methods and sub-methods, it should be readily apparent that a number of modifications may be made without departing from the spirit thereof and that these implementations, implementing components, sub-components, methods and sub-methods may be applied to other wire-in-dam packages and related methods.

What is claimed is:

1. An electromagnetic irradiation system comprising:
a bulb assembly; and
a light emitting diode panel;
wherein the bulb assembly and light emitting diode panel are coupled over a package tray conveyor; and
wherein the bulb assembly and the light emitting diode panel are configured so that a package tray comprising a plurality of image sensor packages encounters irradiation from the light emitting diode panel prior to encountering irradiation from the bulb assembly.

2. The system of claim 1, wherein the light emitting diode panel is a first light emitting diode panel and a second light emitting diode panel is coupled over the package tray conveyor.

3. The system of claim 2, wherein the first light emitting diode panel and second light emitting diode panel are oriented opposing one another with a face of the first light emitting diode panel and a face of the second light emitting diode panel each oriented at an angle relative to a plane formed by the package tray conveyor.

4. The system of claim 3, wherein the angle is between 30 degrees and 45 degrees.

5. The system of claim 3, wherein the angle is 45 degrees.

6. The system of claim 1, wherein the irradiation from the bulb assembly and from the light emitting diode panel is ultraviolet radiation.

7. The system of claim 6, wherein the ultraviolet radiation is used in curing an optically transmissive cover adhesive material.

8. A method of applying a protective layer, the method comprising:
providing an image sensor die comprising a plurality of bond pads;
bonding a plurality of bond wires coupled to the plurality of bond pads;
applying a protective layer over the plurality of bond wires and the plurality of bond pads;
curing the protective layer;
applying an adhesive material directly over the protective layer;
attaching an optically transmissive cover to the adhesive material; and
curing the adhesive material.

9. The method of claim 8, wherein the optically transmissive cover comprises a black mask material applied around a perimeter of the optically transmissive cover.

10. The method of claim 8, wherein curing the adhesive material comprises one of using ultraviolet light, thermal energy, or any combination thereof.

11. The method of claim 8, wherein the protective layer comprises one of a mold compound, an acrylic compound, an organic compound, an epoxy compound, or any combination thereof.

12. The method of claim 8, wherein the protective layer comprises a material that is the same as the adhesive material.

13. The method of claim 12, wherein curing the protective layer comprises one of using ultraviolet light, thermal energy, or any combination thereof.

14. The method of claim 8, further comprising bonding the image sensor die to a substrate.

15. A cover for an image sensor package comprising:
an optically transmissive cover comprising a largest planar side comprising a perimeter having four corners; and
a black mask layer applied onto the largest planar side adjacent to the perimeter forming a mask pattern;
wherein the mask pattern of the black mask layer exposes all four corners of the perimeter.

16. The cover of claim 15, further comprising wherein the mask pattern comprises four segments and only two of the four segments are connected.

17. The cover of claim 15, wherein the mask pattern comprises a stipple pattern.

18. The cover of claim 17, wherein the mask pattern comprises a half tone pattern.

19. The cover of claim 17, wherein the mask pattern is configured to overlap a perimeter of an image sensor die when the optically transmissive cover is coupled over the image sensor die.

20. The cover of claim 19, wherein the largest planar side is one of a largest planar side configured to face the image sensor die or a largest planar side of the optically transmissive cover opposing the largest planar side configured to face the image sensor die.
